(19) United States
(12) Patent Application Publication
(10) Pub. No.: US 2011/0075391 A1
(43) Pub. Date: Mar. 31, 2011

(54) Electronic Apparatus and Circuit Module

(76) Inventor: Kazuyoshi Sasaki, Ome-city (JP)

(21) Appl. No.: 12/786,192

(22) Filed: May 24, 2010

(30) Foreign Application Priority Data
Sep. 30, 2009 (JP) 2009-228937

(51) Int. Cl. H05K 1/14; H05K 7/18

(52) U.S. Cl. 361/796; 361/803

(57) ABSTRACT

According to one embodiment, an electronic apparatus has a circuit module. The circuit module includes a first circuit board having a first side end face on which a first circuit pattern is formed, a second circuit board having a second side end face on which a second circuit pattern is formed, and a flexible wiring board which is in contact with the first side end face and the second side end face to electrically connect the first circuit pattern and the second circuit pattern.

### CROSS-REFERENCE TO RELATED APPLICATIONS

This application claims priority from Japanese Patent Application No. 2009-228937 filed on Sep. 30, 2009, the entire content of which is incorporated herein by reference.

### BACKGROUND

1. Field

One embodiment of the invention relates to an electronic apparatus and a circuit module.

2. Description of the Related Art

In recent years, portable electronic apparatuses have various functions such as a projector function. In such electronic apparatuses, various measures are taken to downsize the apparatus as well as to implement the various functions. For example, JP-A-2004-63569 describes a semiconductor device in which semiconductor chips are stacked, and a conductive layer is formed on a side face of each of the semiconductor chips so as downsize the semiconductor device.

### BRIEF DESCRIPTION OF THE SEVERAL VIEWS OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary perspective view of a projector according to a first embodiment of the invention;

FIG. 2 is an exemplary top view of a video signal generating unit and a lens unit of the projector of FIG. 1;

FIG. 3 is an exemplary perspective view of the projector which is partially cut away to illustrate the video signal generating unit and the lens unit of FIG. 2;

FIG. 4 is an exemplary sectional view of a portion of the projector around the lens unit of FIG. 3;

FIG. 5 is an exemplary side view illustrating how the projector of FIG. 1 is used;

FIG. 6 is an exemplary diagram of a circuit module housed inside the video signal generating unit according to the first embodiment;

FIG. 7 is an exemplary perspective view of the circuit module according to the first embodiment;

FIG. 8 is an exemplary diagram of a flexible wiring board according to the first embodiment;

FIG. 9 is an exemplary diagram of a modified example of a circuit board according to the first embodiment;

FIG. 10 is an exemplary diagram of a modified example of the circuit module according to the first embodiment;

FIG. 11 is an exemplary diagram of a modified example of the flexible wiring board according to the first embodiment; and

FIG. 12 is an exemplary diagram of a circuit module housed in a video signal generating unit according to a second embodiment.

### DETAILED DESCRIPTION

Various embodiments according to the invention will be described hereinafter with reference to the accompanying drawings. In general, according to one embodiment of the invention, an electronic apparatus has a circuit module. The circuit module includes a first circuit board having a first side end face on which a first circuit pattern is formed, a second circuit board having a second side end face on which a second circuit pattern is formed, and a flexible wiring board which is in contact with the first side end face and the second side end face to electrically connect the first circuit pattern and the second circuit pattern.

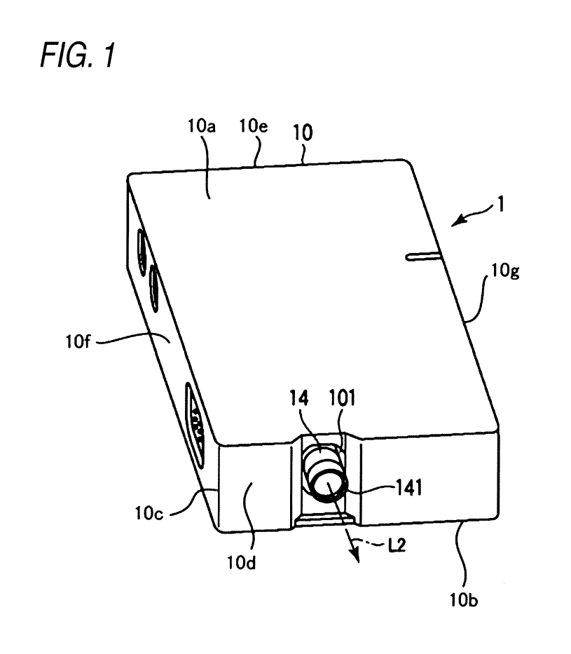

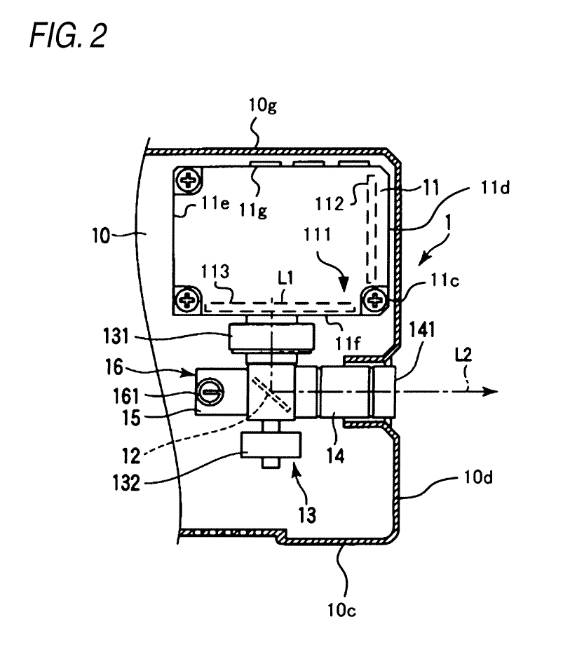

FIG. 1 illustrates a projector 1 according to a first embodiment as an example of an electronic apparatus. The projector 1 will be described below with reference to FIGS. 1 to 5. As shown in FIG. 2, the projector 1 has a body 10 (a housing) defining an outer shape, a video signal generating unit 11, a mirror 12, a bearing unit 13, a lens unit 14, a counter weight 15, and an attenuator 16.

The body 10 has a top wall 10a, a bottom wall 10b which is opposed to the top wall 10a and whose surface serves as a placement surface when the body 10 is placed on something, and a peripheral wall 10c which connects the top wall 10a and the bottom wall 10b. The peripheral wall 10c has a front wall 10d to which the lens unit 14 is attached, a rear all 10e which is opposed to the front wall 10d, and side walls 10f, 10g each of which connects the top wall 10a and the bottom wall 10b and also connects the front wall 10d and the rear wall 10e. A plurality of inner surfaces and inner walls are provided in the body 10. The inner surfaces and inner walls include inner surfaces of the top wall 10a, the bottom wall 10b, the front wall 10d, the rear wall 10e, and the side walls 10f, 10g and walls of housed components.

The video signal generating unit 11 has a top wall 11a, a bottom wall 11b which is opposed to the top wall 11a and the bottom wall 10b of the body 10, and a peripheral wall 11c which connects the top wall 11a and the bottom wall 11b. The walls 11a, 11b, 11c serve as inner walls of the body 10. The peripheral wall 11c has a front wall 11d, a rear wall 11e which is opposed to the front wall 11d, and side walls 11f, 11g each of which connects the top wall 11a and the bottom wall 11b and also connects the front wall 11d and the rear wall 11e.

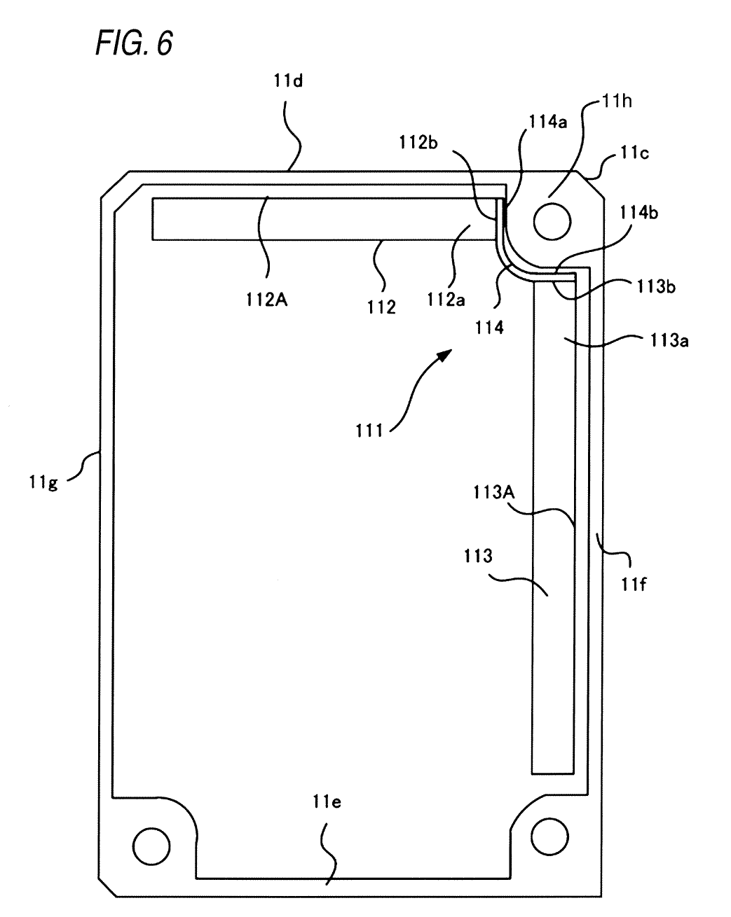

The video signal generating unit 11 incorporates a circuit module 111 which is provided with circuit boards 112, 113 and a flexible wiring board 114 which is electrically connected to the circuit boards 112, 113. The circuit module 111 is composed of electronic components that function as a control section etc. of the video signal generating unit 11. The circuit module 111 will be described later with reference to FIGS. 6-8.

The video signal generating unit 11 incorporates an LED(s) as a light source(s), a display device, a mirror, etc. The video signal generating unit 11 is either of a type using one white LED or of a type using three LEDs (red, green, and blue LEDs). The video signal generating unit 11 emits light carrying a projection image that is formed by the display device.

The mirror 12 is disposed on a light emitting axis L1 of a light beam emitted from the video signal generating unit 11 and reflects (deflects) the light beam by approximately 90°. The bearing unit 13 is composed of a first bearing 131 and a second bearing 132 whose axes coincide with the light emitting axis L1. The first bearing 131 is disposed between the video signal generating unit 11 and the mirror 12. The second bearing 132 is disposed on the opposite side of the mirror 12 to the first bearing 131. The bearing unit 13 supports the mirror 12 so that it is rotatable about the light emitting axis L1.

The lens unit 14 incorporates lenses including a collimation lens and an angle-of-view adjustment lens. The lens unit 14 is disposed on a light projecting axis L2 of a light beam reflected by the mirror 12 in such a manner that the individual lenses are arranged with their axes coincident with the light projecting axis L2. The lens unit 14 is attached to the bearing unit 13 in such a manner as to rotate together with the mirror 12. A tip portion 141 of the lens unit 14 is inserted in a hole 101 of the body 10 and exposed from the body 10 as shown in FIG. 1. As shown in FIG. 5, a projection image M is projected from the lens unit 14 toward a projection surface S which is provided outside the body 10.

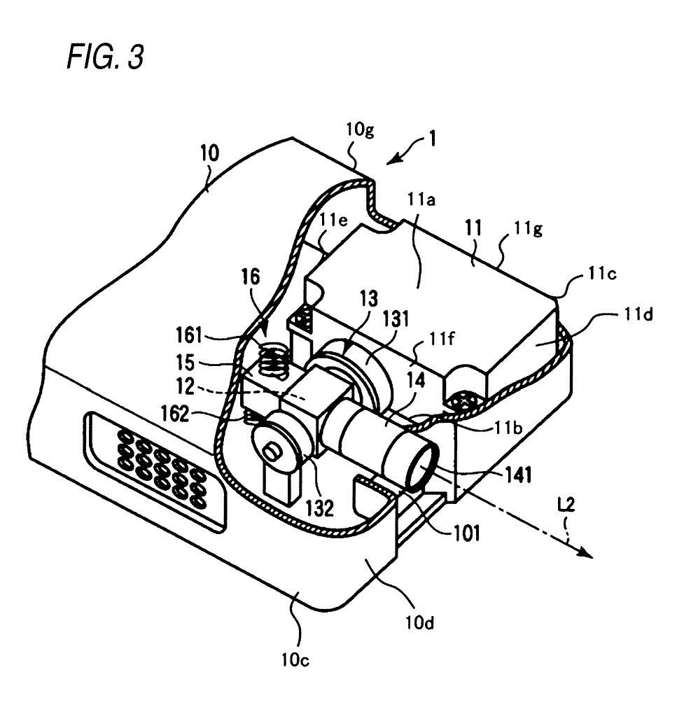

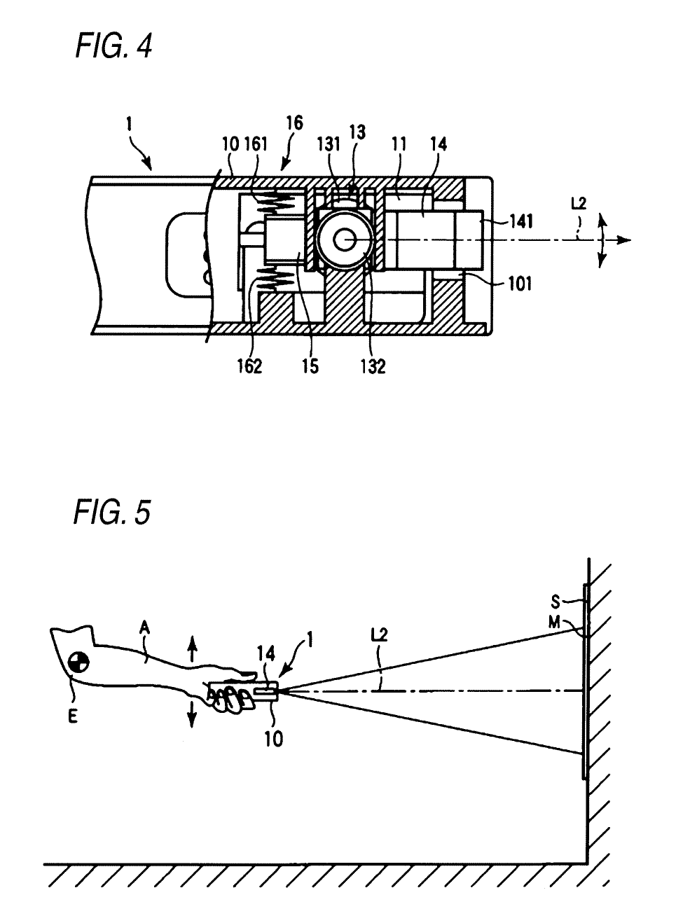

The counter weight 15 is attached to the bearing unit 13 on the opposite side of the light emitting axis L1 to the lens unit 14. The counter weight 15 has such mass as to allow the bearing unit 13 to approximately balance it with the lens unit 14. The attenuator 16 attenuates an angular deviation of the lens unit 14 with respect to the body 10 that is caused when the body 10 is inclined so as to rotate about the light emitting axis L1. For example, as shown in FIGS. 3 and 4, the attenuator 16 is has coil springs 161, 162 which hold the counter weight 15 from both sides in the rotation direction of the bearing unit.

The coil springs 161, 162 may have either the same spring constant or different spring constants. Instead of using the coil springs 161, 162, the counter weight 15 may be supported by a leaf spring or the bearing unit 13 may be provided with a spiral spring. It is also preferable to provide another damper in addition to the coil springs 161, 162. The additional damper may be friction that is set in each of the first bearing 131 and the second bearing 132. In the projector 1, the mirror 12 and the lens unit 14 can rotate freely about the light emitting axis L1. Therefore, even if the body 10 is rotated (moved in the vertical direction) as a result of a rotation of a forearm A about the elbow E, the mirror 12 and the lens unit 14 maintain their postures because of their inertia, that is, they rotate in the direction that is opposite to the rotation direction of the body 10. As a result, in the projector 1, the simple structure that the mirror 12 and the lens unit 14 are supported rotatably by the bearing unit 13 can prevent an event that a projected image M is moved to a large extent because of a hand-movement-induced shake of the projector 1.

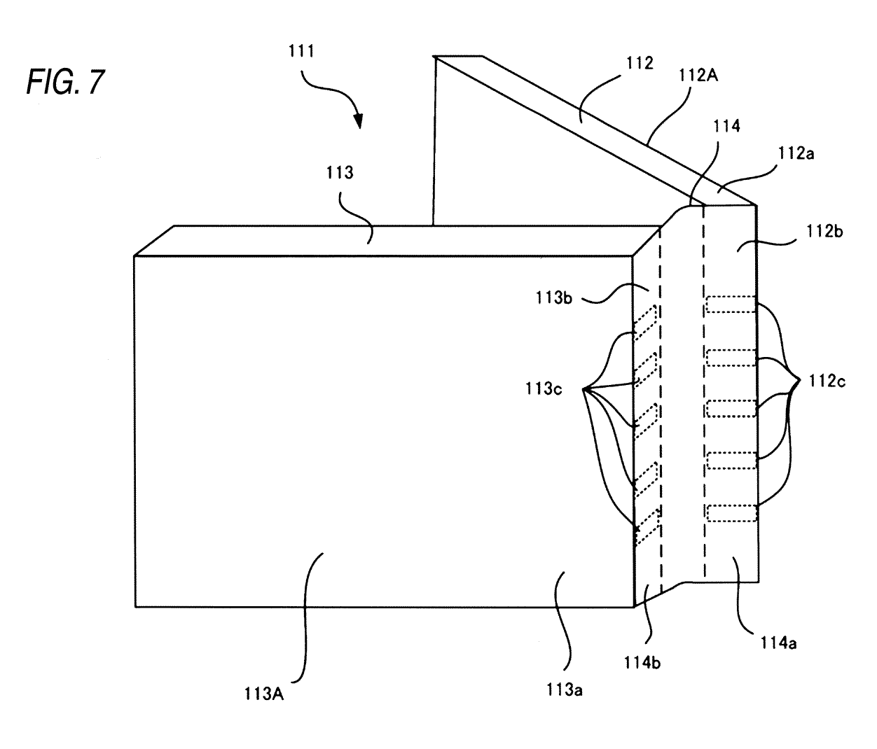

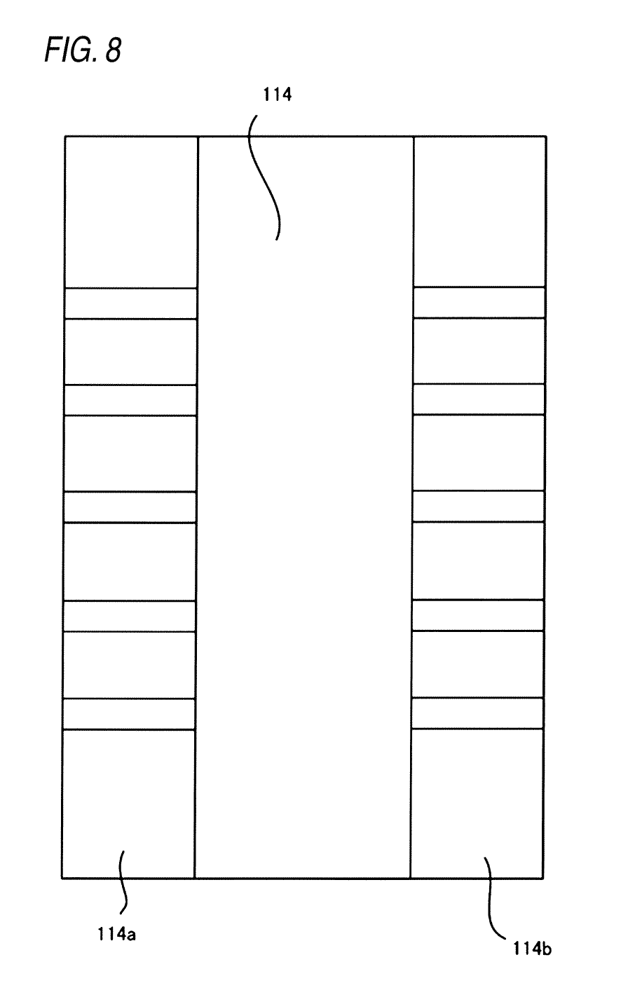

Next, the circuit module 111 according to the embodiment will be described with reference to FIGS. 6-8. FIG. 6 shows the circuit module 111 which is housed in the video signal generating unit 11 used in the embodiment. FIG. 7 is an exemplary perspective view of the circuit module 111 according to the embodiment. FIG. 8 shows the flexible wiring board 114 used in the embodiment.

As shown in FIGS. 6 and 7, the circuit boards 112, 113 are electrically connected to each other by the flexible wiring board 114. The flexible wiring board 114 bridges the circuit boards 112, 113. The circuit boards 112, 113 have respective end portions 112a, 113a which are opposed to each other.

The circuit board 112 has a surface 112A which is opposed to the front wall 11d (an inner wall of the body 10) of the video signal generating unit 11 and is mounted parallel with the front wall 11d. The circuit board 112 has circuit patterns 112c which are formed on a side face 112b of the end portion 112a. The circuit patterns 112c are terminals which extend from wiring patterns (not shown) that are formed on or inside the circuit board 112.

The circuit board 113 has a surface 113A which is opposed to the front wall 11f (an inner wall of the body 10) of the video signal generating unit 11 and is mounted parallel with the side wall 11f. The circuit board 113 has circuit patterns 113c which are formed on a side face 113b of the end portion 113a. The circuit patterns 113c are terminals which extend from wiring patterns (not shown) that are formed on or inside the circuit board 113.

As shown in FIG. 8, two end portions of the flexible wiring board 114 are provided with respective terminal portions 114a, 114b. The terminal portion 114a of the flexible wiring board 114 is in contact with the side face 112b of the end portion 112a of the circuit board 112. The terminal portion 114b of the flexible wiring board 114 is in contact with the side face 113b of the end portion 113a of the circuit board 113. The flexible wiring board 114 is opposed to a corner portion 11h which connects the front wall 11d and the side wall 11f of the video signal generating unit 11 and is part of the peripheral wall lie (an inner wall of the body 10). The corner portion 11h is formed with a hole to be used when the video signal generating unit 11 is mounted using connection members such as screws.

The terminal portion 114a is electrically connected to the circuit patterns 112c which are formed on the side face 112b of the end portion 112a of the circuit board 112. On the other hand, the terminal portion 114b is electrically connected to the circuit patterns 113c which are formed on the side face 113b of the end portion 113a of the circuit board 113.

With the above structure, the embodiment realizes high-density mounting of the housed components. Since the circuit module 111 is provided parallel with the front wall 11d and the side wall 11f of the video signal generating unit 11, the space occupied by the circuit module 111 in the video signal generating unit 11 can be made small.

In the embodiment, the circuit board 112 has the circuit patterns 112c which are formed on the side face 112b of the end portion 112a. The circuit board 113 has the circuit patterns 113c which are formed on the side face 113b of the end portion 113a. The end portions 112a, 113a are opposed to each other, the terminal portion 114a of the flexible wiring board 114 is in contact with the side face 112b, and the terminal portion 114b of the flexible wiring board 114 is in contact with the side face 113b. With this configuration, the length of the flexible wiring board 114 can be made shorter than in a case that the flexible wiring board 114 is connected to conductive paths that are formed on the surface 112A of the circuit board 112 and the surface 113A of the circuit board 113. This realizes cost reduction and also enables high-density mounting because the end portions 112a, 113a can be connected to each other electrically by a short member.

In the embodiment, the side face 112b is substantially parallel to the said wall 11f of the video signal generating unit 11, the side face 113b is substantially parallel to the front wall 11d of the video signal generating unit 11, and the flexible wiring board 114 is disposed along the corner portion 11h of the video signal generating unit 11. To provide a space for, for example, screwing of a screw, the corner portion 11h projects inward than other portions of the peripheral wall 11c. Conventionally, it is difficult to dispose housed components in an area in the vicinity of such a projection (a projected/recessed portion) and such a space is rendered a dead space. In contrast, the structure of the embodiment makes it possible to dispose the circuit module 111 so as to flexibly cope with the projected/recessed portion of the peripheral wall 11c and thereby enables high-density mounting.

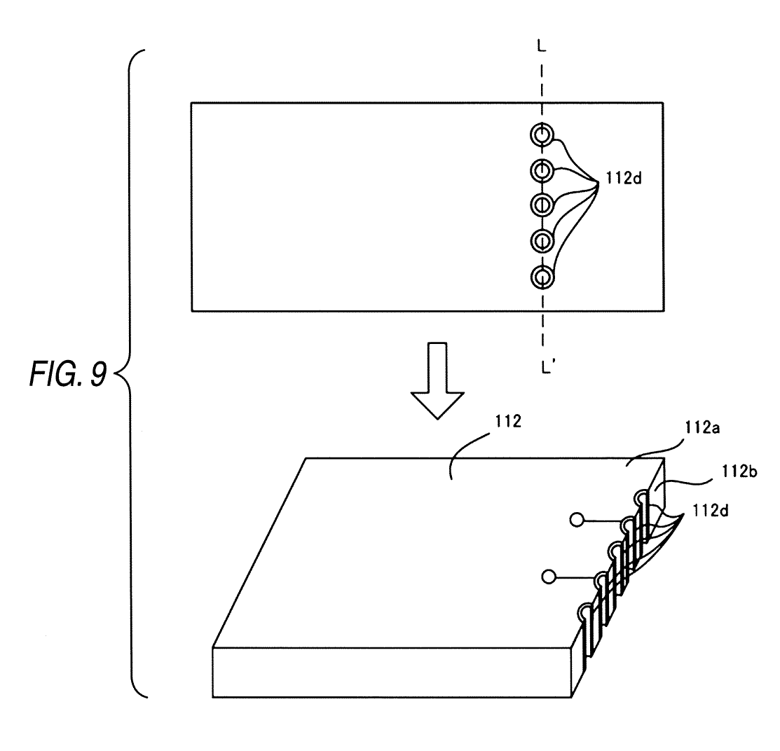

Next, modified examples of the circuit boards 112, 113 will be described with reference to FIG. 9. FIG. 9 illustrates a modified example of the circuit board 112. To simplify the description, the structure of only the circuit board 112 will be described below. However, the same structure can also be applied to the circuit board 113.

As shown in FIG. 9, according to the modified example of the circuit board 112, the circuit patterns 112c formed on the side face 112b of the end portion 112a are conductive layers formed on inner surfaces of grooves. For example, through-holes 112d are formed through a circuit board, and the circuit board is then cut at a plane L-L′ which passes through the respective through holes 112d, whereby the end portion 112a is fowled which has terminals on the side face 112b.

With the above structure, in the modified circuit board 112, conductive terminals can easily be formed on the side face 112b. Where circuit patterns are formed on the side face 112b, the circuit patterns becomes more likely to be peeled or scraped off as the circuit board 112 becomes thinner. In contrast, according to the modified example, since the conductive patterns can be formed at positions that are secluded from the side face 112b, they can be prevented from being peeled or scraped off. The physical durability is thus increased.

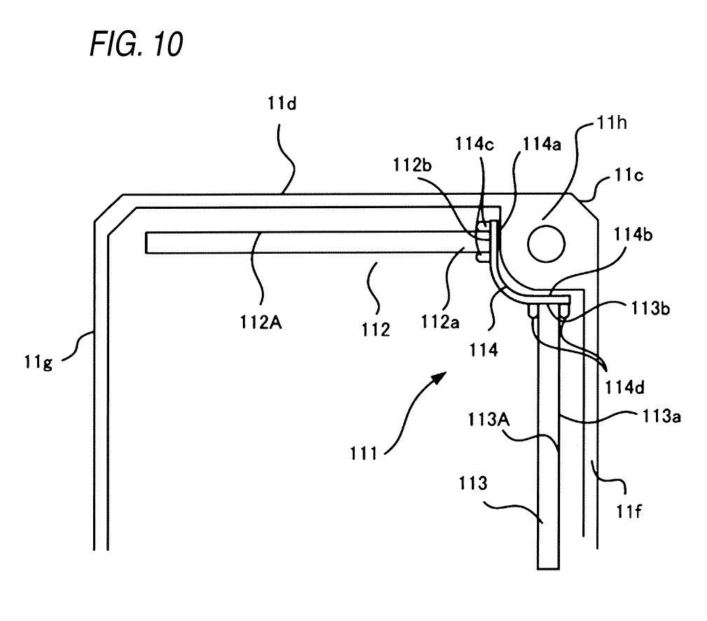

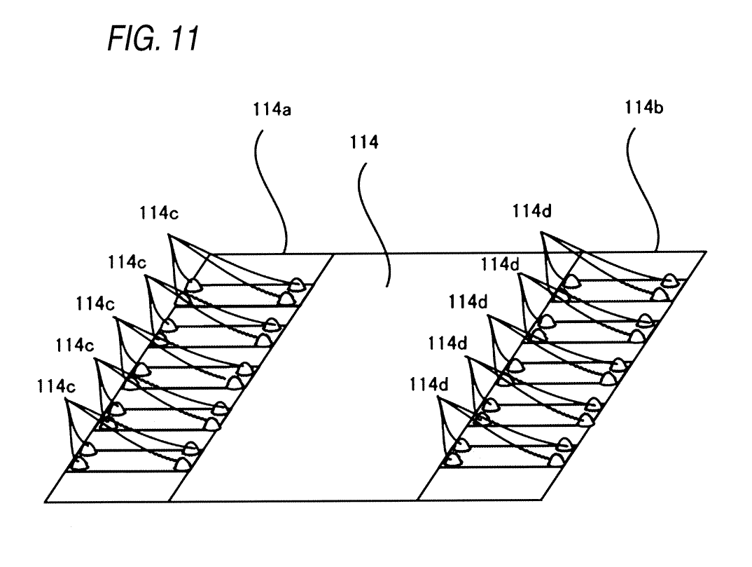

Next, modified examples of the circuit module 111 and the flexible wiring board 114 will be described with reference to FIGS. 10 and 11. FIG. 10 illustrates a modified example of the circuit module 111. FIG. 11 illustrates a modified example of the flexible wiring board 114.

As shown in FIGS. 10 and 11, in the modified examples, projections 114c are formed on the terminal portion 114a, and projections 114d are formed on the terminal portion 114b. For example, the projections 114c, 114d are conductive bumps that are electrically connected to the conductive paths on the flexible wiring board 114. The projections 114c are provided along a perimeter of the terminal portion 114a which is in contact with the side face 112b of the circuit board 112. The projections 114d are provided along a perimeter of the terminal portion 114b which is in contact with the side face 113b of the circuit board 113.

With the above structure, in the modified circuit module 111, the projections 114c, 114d make it possible to clearly recognize those portions of the flexible wiring board 114 which are to be joined to the circuit boards 112, 113 and to thereby facilitate a process of joining the flexible wiring board 114 to the circuit boards 112, 113.

The projections 114c, 114d are conductive bumps. Therefore, the projections 114c, 114d can be electrically connected to conductive patterns that are formed on surfaces, other than the side faces 112b, 113b, of the circuit boards 112, 113. More reliable electrical connections can thus be realized.

Furthermore, the projections 114c are provided so as to surround that region of the terminal portion 114a which is in contact with the side face 112b of the circuit board 112 and the projections 114d are provided so as to surround that region of the terminal portion 114b which is in contact with the side face 113b of the circuit board 113. Therefore, the circuit boards 112, 113 are held in place being sandwiched between the arrays of projections 114c and the arrays of projections 114d, respectively. With this structure, the circuit boards 112, 113 can be fixed to the flexible wiring board 114 in a stable manner.

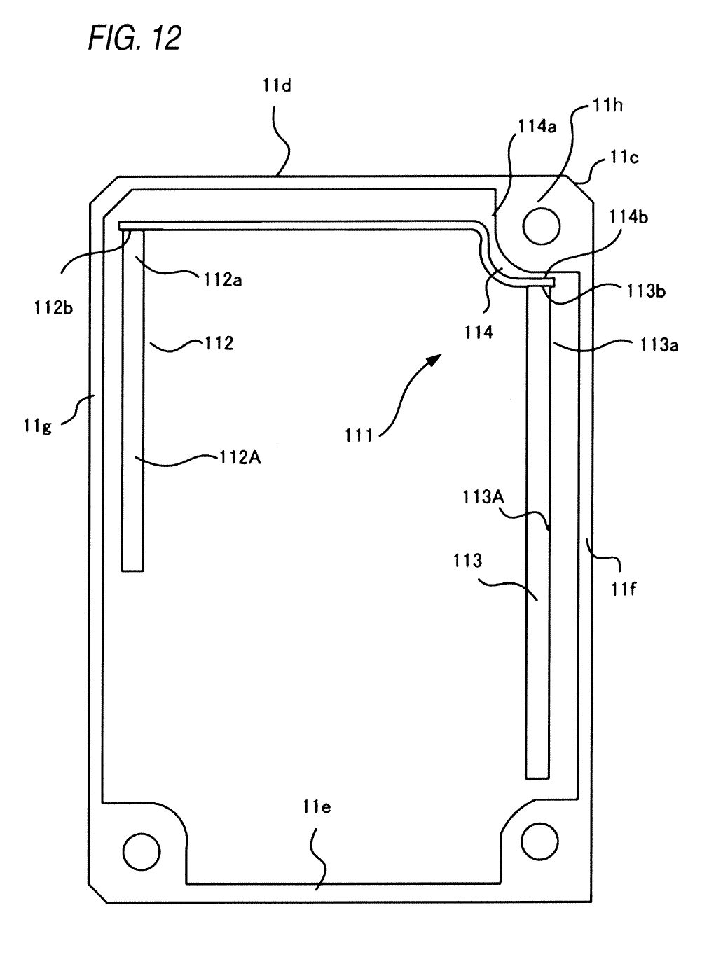

Next, a circuit module 211 according to a second embodiment of the invention will be described with reference to FIG. 12. The circuit module 211 according to the second embodiment is different from the circuit module 111 according to the first embodiment in the structures of the circuit board 112 and the flexible wiring board 114. Therefore, the different portions will mainly be described below and the common portions will not be described by using the same reference symbols. A projector incorporating the circuit module 211 has the same appearance as the projector of FIG. 1 according to the first embodiment.

FIG. 12 shows the circuit module 211 which is housed in the video signal generating unit 11 according to the second embodiment.

As shown in FIG. 12, the circuit boards 112, 113 are electrically connected to each other by the flexible wiring board 114. The flexible wiring board 114 bridges the circuit boards 112, 113. The circuit boards 112, 113 have respective end portions 112a, 113a which are opposed to each other.

The circuit board 112 has a surface 112A which is opposed to the side wall 11g (an inner wall of the body 10) of the video signal generating unit 11 and mounted parallel with the side wall 11g. The circuit board 113 has a surface 113A which is opposed to the side wall 11f (an inner wall of the body 10) of the video signal generating unit 11 and mounted parallel with the side wall 11f. The flexible wiring board 114 is opposed to the front wall 11d (an inner wall of the body 10) of the video signal generating unit 11 and mounted parallel with the front wall 11d.

With the above structure, the second embodiment realizes high-density mounting of the housed components. Since the circuit module 111 is provided parallel with the front wall 11d and the side walls 11f, 11g of the video signal generating unit 11, the space occupied by the circuit module 111 in the video signal generating unit 11 can be made small.

According to the second embodiment, the length of the flexible wiring board 114 can be shortened and the cost can be reduced. And the end portions 112a, 113a can be connected to each other electrically by a short member.

The invention is not limited to the foregoing embodiments but various changes and modifications of its components may be made without departing from the scope of the present invention. Also, the components disclosed in the embodiments may be assembled in any combination for embodying the present invention. For example, some of the components may be omitted from all the components disclosed in the embodiments. Further, components in different embodiments may be appropriately combined.

An electronic apparatus to which the invention is applicable to is not limited to a projector. For example, the invention is also applicable to various electronic apparatus such as a portable computer, a digital camera, a video camera, a personal digital assistant, etc.

What is claimed is:

1. An electronic apparatus comprising:
a housing comprising a first wall, a second wall, and a third wall connecting the first wall and the second wall;
a first circuit board disposed inside the housing so as to be opposed to the first wall, wherein the first circuit board has a first side end face on which a first circuit pattern is formed;
a second circuit board disposed inside the housing so as to be opposed to the second wall, wherein the second circuit board has a second side end face on which a second circuit pattern is formed; and
a flexible wiring board disposed so as to be opposed to a portion of the third wall, wherein the flexible wiring board is in contact with the first side end face and the second side end face to electrically connect the first circuit pattern and the second circuit pattern.

2. The apparatus of claim 1, wherein the third wall forms a corner between the first wall and the second wall,
the first side end face is substantially parallel to the second wall, and
the second side end face is substantially parallel to the first wall.

3. The apparatus of claim 2, wherein the flexible wiring board has projections provided near a region that is in contact with the first side end face and near a region that is in contact with the second side end face.

4. The apparatus of claim 3, wherein the projections include conductive bumps which are electrically connected to conductive paths on the flexible wiring board.

5. The apparatus of claim 4, wherein the conductive bumps are formed along a perimeter of the region that is in contact with the first side end face and along a perimeter of the region that is in contact with the second side end face.

6. The apparatus of claim 1, wherein the first circuit pattern on the first side end face is formed on an inner surface of a groove formed on the first side end face.

7. The apparatus of claim 1, wherein the first wall and the second wall are opposed to each other, and
wherein the flexible wiring board is disposed along the third wall that extends in a direction intersecting with the first wall and the second wall.

8. A circuit module comprising:
a first circuit board having a first side end face on which a first circuit pattern is formed;
a second circuit board having a second side end face on which a second circuit pattern is formed; and
a flexible wiring board which is in contact with the first side end face and the second side end face to electrically connect the first circuit pattern and the second circuit pattern.

9. The module of claim 8, wherein the flexible wiring board has projections provided near a region that is in contact with the first side end face and near a region that is in contact with the second side end face.

10. The module of claim 9, wherein the projections include conductive bumps which are electrically connected to conductive paths formed on the flexible wiring board.
